(19) United States
(12) Patent Application Publication
(10) Pub. No.: US 2025/0202089 A1
(43) Pub. Date: Jun. 19, 2025

(54) DIGITAL ISOLATOR

(71) Applicant: SG MICRO CORP, Beijing (CN)

(72) Inventor: Zhilin Li, Beijing (CN)

(21) Appl. No.: 18/849,531

(22) PCT Filed: Jun. 2, 2023
(86) PCT No.: PCT/CN2023/098025

§ 371 Date: Sep. 22, 2024

(30) Foreign Application Priority Data
Apr. 25, 2022 (CN) 202210441302.7

(51) Int. Cl. H01P 1/36

(52) U.S. Cl. CPC H01P 1/36

(57) ABSTRACT

The present application discloses a digital isolator including a signal transmitting circuit, a signal receiving circuit, and an isolation circuit. The isolation circuit is coupled between the signal transmitting circuit and the signal receiving circuit. The isolation circuit includes a first isolation unit for converting a received input modulation signal into a differential signal and a second isolation unit for providing an output modulation signal in response to receiving the differential signal. The first isolation unit and the second isolation unit have symmetrical circuit structures. By using a fully differential structure and a fully symmetrical structure, the circuit has improved immunity capability, and can suppress common mode transient interference greater than 200 kv/us.

The present application claims priority to the Chinese invention application No. 2022104413027, filed on Apr. 25, 2022, and entitled “DIGITAL ISOLATOR”, the content of which is incorporated herein by reference, including all of the specifications, claims, drawings and abstract.

### TECHNICAL FIELD

The present disclosure relates to the technical field of integrated circuit isolation, and more specifically, to a digital isolator.

### BACKGROUND

A digital isolator is an intermediate circuit that ensures normal interaction of signals between two systems while preventing crosstalk of a DC common mode voltage or interference with an abnormal AC current between two systems. The digital isolator is widely used in the fields of medical, industrial, and communication. With continuous development of technology, the performance requirements for a digital isolator is increased, and the strength of a common mode transient immunity (CMTI) of the digital isolator has become an important indicator for evaluating its performance.

Considering the isolation medium, a digital isolator can be categorized into an optical isolator, a magnetic isolator, and a capacitive isolator. A conventional digital isolator mainly adopts a photoelectric coupling scheme, in which only a light emitting diode and a phototransistor are required to complete signal transmission in an isolation manner. However, due to a limited response time of photoelectric conversion, the data transmission rate is only 10 Mbps. With increasing requirements of various kinds of modern large-scale electronic equipment for electrical isolation characteristics and data transmission rate, the conventional digital isolator with a photoelectric coupling scheme has become increasingly unable to meet the demand. The capacitive coupling digital isolator uses a capacitor as an electrical isolation device, and needs collaboration of a modulation driver and a demodulation circuit. The data transmission rate can be higher than that of the photoelectric coupling digital isolator. However, due to the restriction of a breakdown voltage of the capacitor, it is not suitable for an electrical isolation system which needs a high breakdown voltage and a small isolation capacitance. A magnetic coupling digital isolator adopts an electromagnetic coupling scheme, and can achieve the data transmission rate of up to 100 Mbps, when operates together with peripheral modulation driver and demodulation circuit. Moreover, transformer coils have a high breakdown voltage and a low capacitance between lines, which results in a breakdown voltage of more than 5 kV and an extremely small isolation capacitance. The magnetic coupling digital isolator has been widely used by advanced electrical systems. However, a transformer structure has a large size and poor electromagnetic compatibility and a high cost. In the magnetic coupling scheme, an organic material such as Polyimide is used as the insulation medium, which has low insulation strength, poor stability, and a short life when compared with SiO2 as insulation medium in a capacitive coupling scheme. For a long time, the magnetic coupling digital isolator has the greatest size and most complex structure.

FIG. 1 is a schematic circuit diagram of a traditional digital isolator, using OOK modulation and demodulation technology, consisting of a transmitting circuit TX and a receiving circuit RX, transmitting the digital signal with high and low levels by sending and not sending a high-frequency clock signal.

Components of the transmitting circuit TX and the receiving circuit RX circuit are coupled with each other in the manner shown in FIG. 1. The transmitting circuit TX includes a digital signal input TX_DATA, an oscillator OSC, isolation capacitors Ciso1 and Ciso2, and the receiving circuit RX includes isolation capacitors Ciso3 and Ciso4, two-stage amplification circuits AMP1 and AMP2, a comparator COMP, and grounded resistors R1 and R2. The isolation capacitors Ciso1 and Ciso3 are coupled with each other, and isolation capacitors Ciso1 and Ciso3 are coupled with each other, by bonding wires Wire1 and Wire2, respectively.

The conventional digital isolator has limited input common mode range, and can only suppress common mode transient interference of 50˜100 kv/us. When large common mode transient interference occurs, the digital isolator still has the risk of communication failure. Moreover, the conventional digital isolator cannot reuse the design for a transmission circuit TX and a receiving circuit RX. Especially, in a case that there are a plurality of channels and different transmission directions, each product needs to be redesigned, increasing the cost of design and manufacturing.

### SUMMARY

In view of the above problems, it is an object of the present disclosure to provide a digital isolator that improves immunity capability of the circuit and can suppress higher common mode transient interference.

According to an aspect of the present disclosure, there is provided a digital isolator comprising: a signal transmitting circuit, a signal receiving circuit, and an isolation circuit coupled between the signal transmitting circuit and the signal receiving circuit, the isolation circuit comprising: a first isolation unit, configured to convert a received input modulation signal into a differential signal; a second isolation unit, configured to provide an output modulation signal in response to receiving the differential signal, wherein the first isolation unit and the second isolation module have symmetrical circuit structures.

Optionally, the signal transmitting circuit is configured to shape and modulate an input signal to generate a modulation signal; the signal receiving circuit is configured to demodulate the output modulation signal to generate an output signal.

Optionally, each of the first isolation unit and the second isolation unit comprises: a first inductor coil and a second inductor coil coupled to a common end, the first inductor coil and the second inductor coil converting a modulation signal into the differential signal, or converting the differential signal into a modulation signal.

Optionally, the first inductor coil and the second inductor coil are respective portions of a differential inductor coil.

Optionally, the first inductor coil and the second inductor coil are discrete inductor coils.

Optionally, each of the first isolation unit and the second isolation unit comprises: an isolation capacitor unit, configured to transmit the differential signal in an isolated manner.

Optionally, the isolation capacitor unit comprises a first, a second, a third and a fourth capacitor, wherein the first capacitor and the second capacitor are coupled between a first port of the isolation capacitor unit and a reference ground, with a common end configured to input/output one polarity of the differential signal, the third capacitor and the fourth capacitor are coupled between a second port of the isolation capacitor unit and the reference ground, with a common end configured to input/output the other polarity of the differential signal.

Optionally, the first port of the isolation capacitor unit in the first isolation unit is coupled with the first port of the isolation capacitor unit in the second isolation unit through a first bonding wire, and the second port of the isolation capacitor unit in the first isolation unit is coupled with the second port of the isolation capacitor unit in the second isolation unit through a second bonding wire.

Optionally, the capacitance values of the first capacitor and the third capacitor are equal to each other, and the capacitance values of the second capacitor and the fourth capacitor are equal to each other.

Optionally, the capacitance value of the second capacitor is much larger than that of the first capacitor, and the capacitance value of the fourth capacitor is much larger than that of the third capacitor.

Optionally, the first isolation unit and the second isolation unit are provided in different dies.

Optionally, the signal transmitting circuit includes a shaping unit and a modulation unit; the signal receiving circuit comprises a demodulation unit and a driving unit.

Optionally, the shaping unit comprises a Schmitt trigger.

Optionally, the signal transmitting circuit further comprises a first high-frequency oscillator configured to generate a first high-frequency carrier signal.

Optionally, the signal receiving circuit further comprises a second high-frequency oscillator configured to generate a second high-frequency carrier signal.

According to another aspect of the present disclosure, there is provided a system comprising: a first circuit, configured to provide an input signal; the digital isolator described above, comprising: an isolation circuit comprising: a first isolation unit, configured to convert a received input modulation signal corresponding to the input signal into a differential signal; a second isolation unit, configured to provide an output modulation signal in response to receiving the differential signal, wherein the first isolation unit and the second isolation module have symmetrical circuit structures; and a second circuit, configured to receive an output signal corresponding to the output modulation signal, wherein the first circuit and the second circuit are configured to operate at different voltage levels.

Optionally, the digital isolator further comprises: a signal transmitting circuit, configured to shape and modulate a received input signal to generate an input modulation signal, and a signal receiving circuit configured to demodulate the output modulation signal to generate the output signal.

In summary, the isolation circuit in the digital isolator according to the present disclosure consists of two isolation units being symmetrical with each other. The two isolation units transmit signal by converting an input modulation signal into a differential signal at a transmitting side and then convert the differential signal into an output modulation signal at a receiving side. By using a full differential structure, the circuit has improved immunity capability, and can suppress common mode transient interference greater than 200 kv/us. Moreover, the isolation circuit according to the present disclosure has a large impedance due to high-frequency resonance of a differential inductor and large capacitors, and obtains a signal with a larger voltage amplitude after voltage division by small capacitors, further enhancing the immunity capability of the circuit.

### BRIEF DESCRIPTION OF THE DRAWINGS

The foregoing and other objects, features and advantages of the present disclosure will become clearer by the following description of embodiments of the present disclosure with reference to the accompanying drawings.

FIG. 1 is a schematic circuit diagram of a conventional digital isolator;

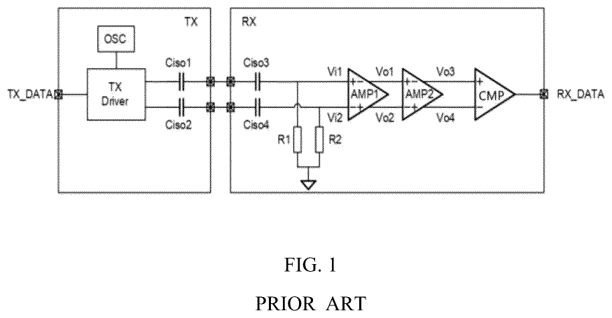

FIG. 2 is a schematic diagram of circuit structure of a digital isolator according to the present disclosure;

FIG. 3 is a schematic diagram of circuit structure of an isolation circuit according to the present disclosure;

FIG. 4 is a schematic diagram of structure of a digital isolator according to the present disclosure;

FIG. 5 is simulated waveforms of a digital isolator according to the present disclosure;

FIG. 6 is a schematic diagram of circuit structure of a multi-channel digital isolator according to the present disclosure;

FIG. 7 is a schematic diagram of a system according to the present disclosure, comprising a first circuit and a second circuit that can communicate with each other via a digital isolator.

### DETAILED DESCRIPTION

Various embodiments of the present disclosure will be described in more detail below with reference to the accompanying drawings. In the various figures, the same elements are denoted by the same or similar reference numerals. For the sake of clarity, various parts in the accompanying drawings are not drawn to scale.

It should be understood that in the following description, the word “circuit” refers to a conductive circuit consisting of at least one element or sub-circuit through electrical coupling or electromagnetic coupling. Conversely, when the element is said to be “directly coupled” or “directly connected” to another element, it means that there is no intermediate element therebetween.

The present disclosure will be described in detail below in conjunction with the accompanying drawings and specific embodiments.

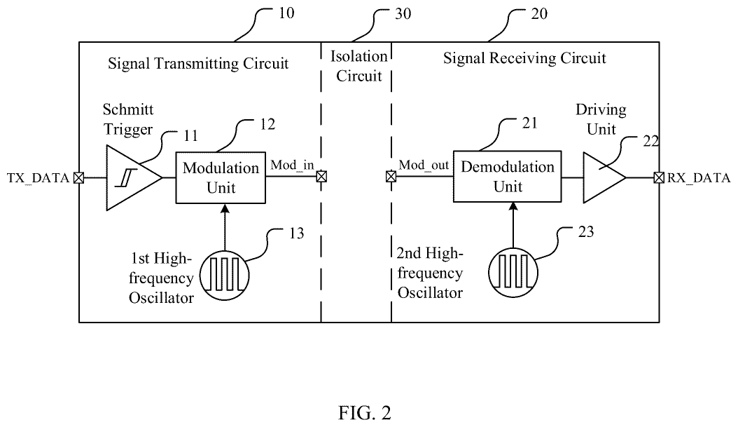

FIG. 2 shows a main architecture of a digital isolator according to the present disclosure. The digital isolator is often used to deal with the problem that a controlling side and a controlled side do not have a common ground. When references of the two sides jitter with respect to each other, common mode transient interference will occur, which leads to the failure of communication in the digital isolator. As shown in FIG. 2, in general, the digital isolator includes a signal transmitting circuit 10, a signal receiving circuit 20, and an isolation circuit 30 between them. The signal transmitting circuit 10 and the signal receiving circuit 20 are different dies, which are placed on two islands being isolated from each other in a package, in an actual application. The signal transmitting circuit 10 includes a shaping unit 11, a modulation unit 12, and a first high-frequency oscillator 13. The shaping unit 11 shapes an input signal TX_DATA to obtain a clean square wave signal. The first high-frequency oscillator 13 generates a first high-frequency carrier signal, and the modulation unit 12 modulates the input signal after shaping to a carrier frequency to generate an input modulation signal Mod_in. The input modulation signal Mod_in after modulation is sent to an input of the isolation circuit 30. The isolation circuit 30 is configured to provide an output modulation signal Mod_out to the side of the signal receiving circuit 20 in response to the received input modulation signal Mod_in.

The signal receiving circuit 20 includes a demodulation unit 21, a driving unit 22, and a second high-frequency carrier oscillator 23. Here, the second high-frequency carrier oscillator 23 is configured to generate a second high-frequency carrier signal and send it to the demodulation unit 21. The demodulation unit 21 is configured to integrate the received modulation signal Mod_out and then sample and count the signal with a carrier frequency determined by the second high frequency carrier oscillator 23. The driving unit 22 is used to amplify the signal demodulated by the demodulation unit 21 for driving, to generate an output signal RX_DATA to drive a post-stage load.

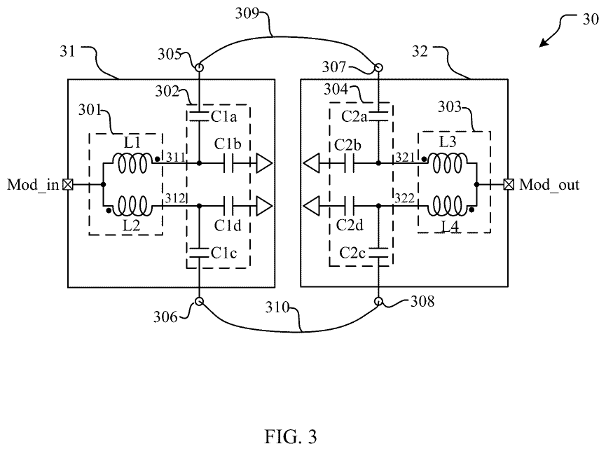

FIG. 3 shows a schematic diagram of circuit structure of an isolation circuit 30 according to the present disclosure. As shown in FIG. 3, the isolation circuit 30 according to the present disclosure includes a first isolation unit 31 on the side of the signal transmitting circuit 10 and a second isolation unit 32 on the side of the signal receiving circuit 20. In an actual application, the first isolation unit 31 and the signal transmitting circuit 10 are placed on one die, and the second isolation unit 32 and the signal receiving circuit 20 are placed on another die that is isolated from the one die. Here, the first isolation unit 31 is configured to convert a received input modulation signal Mod_in into a differential signal, and the second isolation unit 32 is configured to provide an output modulation signal Mod_out in response to the received differential signal.

The first isolation unit 31 includes a signal conversion element 301 and an isolation capacitor unit 302, and the second isolation unit 32 includes a signal conversion element 303 and an isolation capacitor unit 304. Here, the signal conversion element 301 is used to convert the input modulation signal Mod_in into a pair of polarities 311 and 312 of a differential signal. The isolation capacitor unit 302 is used to transmit the differential signal to the second isolation unit 32. The isolation capacitor unit 304 is used to provide the received differential signal to the signal conversion element 303, and the received pair of polarities 311 and 312 of the differential signal are converted into an output modulation signal Mod_out by the signal conversion element 303.

Here, the signal conversion elements 301 and 303 are implemented, for example, by inductors. In one embodiment, the signal conversion element 301 is implemented by discrete inductor coils L1 and L2, with a common end of the inductor coils L1 and L2 which is configured to be coupled to the input modulation signal Mod_in, and free ends of the inductor coils L1 and L2 which are used to provide the pair of polarities 311 and 312 of the differential signal, respectively. The signal conversion element 303 is implemented by discrete inductor coils L3 and L4, with free ends of the inductor coils L3 and L4 which is used to receive the pair of polarities 321 and 322 of the differential signal, respectively, and a common end of the inductor coils L3 and L4 which is used to provide the output modulation signal Mod_out.

In another embodiment, the signal conversion elements 301 and 303 may also be implemented by a differential inductor coil (not shown in FIG. 2). An intermediate tap of the differential inductor coil of the signal conversion element 301 is configured to be coupled to the input modulation signal Mod_in, and the two ends are configured to provide the pair of polarities 311 and 312 of the differential signal. Two ends of a differential inductor coil of the signal conversion element 303 are configured to receive the pair of polarities 321 and 322 of the differential signal, with an intermediate tap which is configured to provide an output modulation signal Mod_out. The use of differential inductor coil not only reduces an area of the chip, but also reduces coupling capacitance between coils and improves the efficiency of signal transmission.

The isolation capacitor unit 302 includes isolation capacitors C1a, C1b, C1c, and Cld. Here, the capacitors C1a and C1b are coupled between the port 305 of the isolation capacitor unit 302 and a reference ground, with a common end which is coupled with an output of the signal conversion element 301 to receive the polarity 311 of the differential signal. The capacitors C1c and C1d are coupled between the other port 306 of the isolation capacitor unit 302 and the reference ground, with a common end which is coupled with the other output of the signal conversion element 301 to receive the polarity 312 of the differential signal. It should be noted that, in the isolation capacitor unit 302, the capacitance value of the isolation capacitor C1b is much larger than the capacitance value of the isolation capacitor C1a, the capacitance value of the isolation capacitor C1d is much larger than the capacitance C1c, and the capacitance value of the isolation capacitor C1a is equal to the capacitance value of the isolation capacitor C1c, the capacitance value of the isolation capacitor C1b is equal to the capacitance value of the isolation capacitor C1d. That is, the isolation capacitors C1b and C1d are called large capacitors, and the isolation capacitors C1a and C1c are called small capacitors. During signal transmission, the signal conversion element 301 has a large impedance due to the high-frequency resonance of the differential inductor and the large capacitors C1b and C1d, and obtains a signal with a larger voltage amplitude after voltage division by small capacitors C1a and C1c, further enhancing the immunity capability of the circuit. Meanwhile, the small capacitors C1a and C1c require a smaller area, which facilitates reducing the cost of the circuit.

Similarly, the isolation capacitor unit 304 includes capacitors C2a, C2b, C2c, and C2d. Here, the capacitors C2a and C2b are coupled between a port 307 of the isolation capacitor unit 304 and a reference ground, with a common end which is coupled with an input of the signal conversion element 303 to provide the polarity 321 of the differential signal. The capacitors C2c and C2d are coupled between the other port 308 of the isolation capacitor unit 304 and a reference ground, with a common end which is coupled with the other input of the signal conversion element 303 to provide the polarity 322 of the differential signal. It should be noted that, in the isolation capacitor unit 304, the capacitance value of the isolation capacitor C2b is much larger than the capacitance value of the isolation capacitor C2a, the capacitance value of the isolation capacitor C2d is much larger than the capacitance C2c, and the capacitance value of the isolation capacitor C2a is equal to the capacitance value of the isolation capacitor C2c, the capacitance value of the isolation capacitor C2b is equal to the capacitance value of the isolation capacitor C2d. That is, the isolation capacitors C2b and C2d are called large capacitors, and the isolation capacitors C2a and C2c are called small capacitors. During signal transmission, the signal conversion element 303 has a large impedance due to the high-frequency resonance of the differential inductor and the large capacitors C2b and C2d, and obtains a signal with a larger voltage amplitude after voltage division by small capacitors C2a and C2c, further enhancing the immunity capability of the circuit. Meanwhile, the small capacitors C2a and C2c require a smaller area, which facilitates reducing the cost of the circuit.

Moreover, the isolation circuit 30 according to the present disclosure also includes a first bonding wire 309 and a second bonding wire 310. The first bonding wire 309 is used for electrically coupling the port 305 of the isolation capacitor unit 302 with the port 307 in the isolation capacitor unit 304. The second bonding wire 310 is used for electrically coupling the port of in the isolation capacitor unit 302 with the port 308 of the isolation capacitor unit 304.

The present disclosure does not limit the implementation of the bonding wires. The bonding wires provide only a signal transmission channel between the isolation units of the present disclosure. Any implementation that can achieve electrical connection is within the scope of protection of the present disclosure.

In summary, the first isolation unit 31 and the second isolation unit 32 in the isolation circuit 30 according to the present disclosure have a symmetrical structure with respect to each other, which facilitates improving the immunity capability of the circuit and can suppress common mode transient interference greater than 200 kv/us. Moreover, the isolation circuit 30 according to the present disclosure has a large impedance due to high-frequency resonance of a differential inductor and large capacitors, and obtains a signal with a larger voltage amplitude after voltage division by small capacitors, further enhancing the immunity capability of the circuit.

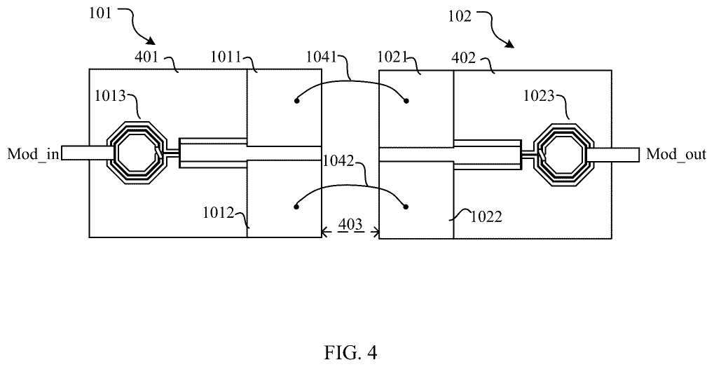

FIG. 4 is a schematic diagram of structure of a digital isolator according to the present disclosure. As shown in FIG. 4, the digital isolator according to the present disclosure includes two chips 101 and 102, with a signal transmitting circuit on the chip 101 and a signal receiving circuit on the chip 102. Certainly, in some other examples, a signal receiving circuit may be provided on the chip 101, and a signal receiving circuit may be provided on the chip 102, without limitation to this herein. Further, for ease illustration and simplification of the drawings, the transmitting circuit and the receiving circuit are not shown in FIG. 4.

Here, a pair of capacitors 1011 and 1012, and a differential inductor coil 1013, are arranged on the chip 101. A pair of capacitors 1021 and 1022, and a differential inductor coil 1023, are arranged on the chip 102. The differential inductor coils 1013 and 1023 include a communication metal coil with at least 3 turns wounded along a single path. The path includes ports at both ends and a plurality of cross structures. The metal coil is wounded in a clockwise or counterclockwise direction, with two ports which are arranged at the bottom of the outermost ring, and an intermediate tap which is arranged at the top of the outermost ring. The intermediate tap of the differential inductor coil 1013 is coupled to the input modulation signal Mod_in, and the ports at both ends are coupled to lower plates of the capacitors 1011 and 1012. The intermediate tap of the differential inductor coil 1023 is coupled to the output modulation signal Mod_out, and the ports at both ends are coupled to lower plates of the capacitors 1021 and 1022. An upper plate of the capacitor 1011 is coupled with an upper plate of the capacitor 1021 through a bonding wire 1041, and an upper plate of the capacitor 1012 is coupled with an upper plate of the capacitor 1022 through the bonding wire 1042.

The chip 101 and the chip 102 are attached to two metal islands 401 and 402 that are isolated from each other. Metal islands are common structures in a chip package and are widely used in SOP, QFN, DIP, SIP and other packaging forms. A distance 403 between the metal islands 401 and 402 determines a withstand voltage of the digital isolator. The smaller the distance, the higher the withstand voltage. In practice, the distance 403 between the metal islands 401 and 402 can be determined according to the demand for the withstand voltage.

In this embodiment, the capacitors 1011 and 1012 in the chip 101 may correspond to the small capacitors C1a and C1c in FIG. 3, respectively, the capacitors 1021 and 1022 in the chip 102 may correspond to the small capacitors C2a and C2c in FIG. 3, respectively. The large capacitors C1b, C1d, C2b and C2d in FIG. 3 may be implemented by parasitic capacitors. It is known that there are parasitic capacitors between a local ground and those connectors for coupling to the transmitting circuit. Therefore, in an actual manufacturing process, the small capacitors C1a, C1c, C2a and C2c in the digital isolator according to the embodiment of the present disclosure may be provided only in the chips, which facilities reducing an area of the chip and reducing the manufacturing cost.

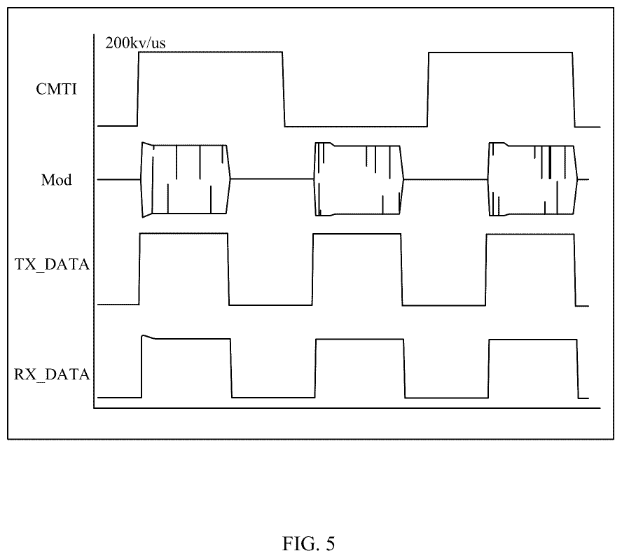

FIG. 5 is simulated waveforms of a digital isolator according to the present disclosure. The input signal TX_data is a square wave signal. After passing through the signal transmitting circuit 10, a high level is modulated into a high frequency signal, and a low level remains unchanged, so as to obtain a modulation signal Mod. After passing through the isolation circuit 30, the modulation signal Mod is demodulated by the signal receiving circuit 20 and restored to a normal square wave signal, which is the output signal RX_data. The signal CMTI in FIG. 5 is a common mode transient interference signal of 200 kv/us externally applied. As can be seen from the waveforms in FIG. 5, the modulation signal Mod in this embodiment is hardly influenced by the common mode transient interference signal CMTI during the process of passing through the isolation circuit 30, and can still obtain a normal output signal RX_DATA at the signal receiving circuit 20. Therefore, the digital isolator according to the present disclosure has a common mode transient interference suppression capability much greater than 200 kv/us, which is far superior to a conventional digital isolator.

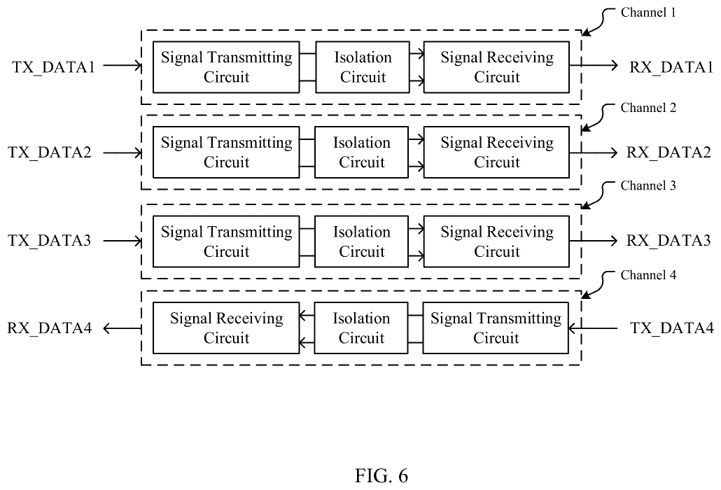

FIG. 6 is a schematic diagram of circuit structure of a multi-channel digital isolator according to the present disclosure. As an alternative embodiment, see FIG. 6, the digital isolator includes a plurality of channels (4 channels as shown in the figure) arranged side by side, each of which includes a signal transmitting circuit, a signal receiving circuit, and an isolation circuit therebetween. As having mentioned above, the isolation circuit according to the embodiment of the present disclosure is implemented by a first isolation unit and a second isolation unit that are symmetrical with respect to each other. Also, the signal transmitting circuit and the signal receiving circuit may be arranged to be symmetrical with respect to each other. Therefore, in an actual design process, signal transmission directions of various channels may be adjusted like building blocks, allowing for a multi-channel product with different signal transmission directions being formed in a single wafer, without incurring additional design and manufacturing costs.

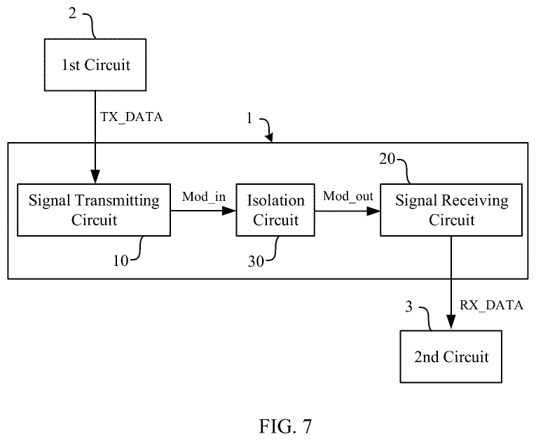

FIG. 7 is a schematic diagram of a system according to the present disclosure, comprising a first circuit and a second circuit that can communicate with each other via a digital isolator. In an example of the system shown in FIG. 7, the system may include a first circuit 2 and a second circuit 3 that communicate with each other via a digital isolator 1. The first circuit 2 may have a first voltage level, and the second circuit 3 may have a second voltage level that is different from the first voltage level. In one example, the first voltage level may be a relatively low voltage level (e.g., about 0 to 100 V), and the second voltage level may be a relatively high voltage level (e.g., 1 kV to 15 kV). In one example, the first circuit 2 may be implemented by a low-power IC chip (e.g., a computer, a controller, etc.), and the second circuit 3 may be implemented by a high-power circuit component (e.g., an industrial transformer, a high-power transmitter, etc.). In this example, the first circuit 2 and the second circuit 3 may have ground references that are isolated from each other, such that there is no a common ground between the first circuit 2 and the second circuit 3. That is, the first circuit 2 and the second circuit 3 may have different ground potential. Thus, in this example, electrical coupling (e.g., via conductive wires) between the first circuit 2 and the second circuit 3 may cause damage to components in the first circuit 2 and/or the second circuit 3.

To avoid this damage, the digital isolator 1 enables communication between the first circuit and the second circuit. The digital isolator 1 may include a signal transmitting circuit 10, which may receive data from the first circuit 2. The data is, for example, a digital signal, such as a binary data signal referred to as a data signal. The data signal may be, for example, a series of pulses. The input circuit 10 may be configured to modulate a data signal onto a carrier signal to obtain a signal which may be referred to as an input modulation data signal. In some examples, the carrier signal may be a signal having a frequency of about 1 GHz to about 6 GHz. Other frequencies may be used for the carrier signal. In some examples, the input modulation data signal may be a pulse width modulated (PWM) signal, a pulse code modulated (PCM) signal, etc. In some examples, an input modulation data signal may be provided in a burst mode and/or asynchronously. The input modulation data signal may be provided to the isolation circuit 30. The isolation circuit 30 may be configured with a first isolation unit and a second isolation unit. The first isolation unit can convert a received input modulation data signal into a differential signal, and isolates and transmits the differential signal to the second isolation unit. The second isolation unit provides an output modulation signal in response to the received differential signal. The signal receiving circuit 20 may be configured to demodulate the output modulation signal and adjust the output modulation signal to generate an output data signal. The output data signal may have a voltage level corresponding to the voltage level (i.e. the second voltage level) of the second circuit. Thus, the first circuit 2 may transmit data to the second circuit 3 at a relatively high data rate (e.g., up to or greater than about 500 Mbps) while still maintaining a current isolation, thereby reducing and/or eliminating possibility of damage to the second circuit 3 by the first circuit 2, or vice versa.

In summary, the isolation circuit in the digital isolator according to the present disclosure consists of two isolation units being symmetrical with each other. The two isolation units transmit signal by converting an input modulation signal into a differential signal at a transmitting side and then convert the differential signal into an output modulation signal at a receiving side. By using a full differential structure, the circuit has improved immunity capability, and can suppress common mode transient interference greater than 200 kv/us. Moreover, the isolation circuit according to the present disclosure has a large impedance due to high-frequency resonance of a differential inductor and large capacitors, and obtains a signal with a larger voltage amplitude after voltage division by small capacitors, further enhancing the immunity capability of the circuit.

Moreover, the isolation circuit according to the embodiment of the present disclosure is implemented by a first isolation unit and a second isolation unit that are symmetrical with respect to each other. Also, the signal transmitting circuit and the signal receiving circuit may be arranged to be symmetrical with respect to each other. Therefore, in an actual design process, signal transmission directions of various channels may be adjusted like building blocks, allowing for a multi-channel product with different signal transmission directions being formed in a single wafer, without incurring additional design and manufacturing costs.

It should be noted that relational terms such as first and second, etc. are used herein solely to distinguish one entity or operation from another entity or operation and do not necessarily require or imply the existence of any such actual relationship or order between such entities or operations. Furthermore, the word “include”, “contain”, or any other variation thereof is intended to cover non-exclusive inclusion, so that a process, method, article, or device including a series of elements includes not only those elements, but other elements that are not explicitly listed or elements inherent to such process, method, article, or device. In the absence of further limitations, elements defined by the phrase “comprises a . . . ” do not exclude the presence of additional identical elements in the process, method, article, or device that includes the elements.

In accordance with embodiments of the present disclosure, such as those described above, these embodiments do not describe all details in detail, nor do they limit the invention to specific embodiments only. Obviously, a lot of modifications and changes can be made based on the above description. These embodiments are selected and specifically described in this specification in order to better explain the principles and practical applications of the present disclosure, so that those skilled in the art can make good use of the present disclosure and its modifications on the basis of the present disclosure. The scope of protection of the present disclosure shall be subject to the scope defined in the claims of the present disclosure.

1. A digital isolator comprising: a signal transmitting circuit, a signal receiving circuit, and an isolation circuit coupled between the signal transmitting circuit and the signal receiving circuit, the isolation circuit comprising:
a first isolation unit, configured to convert a received input modulation signal into a differential signal;
a second isolation unit, configured to provide an output modulation signal in response to receiving the differential signal,
wherein the first isolation unit and the second isolation unit have symmetrical circuit structures.

2. The digital isolator according to claim 1, wherein
the signal transmitting circuit is configured to shape and modulate a received input signal to generate an input modulation signal;
the signal receiving circuit is configured to demodulate the output modulation signal to generate an output signal.

3. The digital isolator according to claim 1, wherein each of the first isolation unit and the second isolation unit comprises:
a first inductor coil and a second inductor coil coupled to a common end, the first inductor coil and the second inductor coil converting a modulation signal into the differential signal, or converting the differential signal into a modulation signal.

4. The digital isolator according to claim 3, wherein the first inductor coil and the second inductor coil are respective portions of a differential inductor coil.

5. The digital isolator according to claim 3, wherein the first inductor coil and the second inductor coil are discrete inductor coils.

6. The digital isolator according to claim 1, wherein each of the first isolation unit and the second isolation unit comprises:
an isolation capacitor unit, configured to transmit the differential signal in an isolated manner.

7. The digital isolator according to claim 6, wherein the isolation capacitor unit comprises a first, a second, a third and a fourth capacitor,
wherein the first capacitor and the second capacitor are coupled between a first port of the isolation capacitor unit and a reference ground, with a common end configured to input/output one polarity of the differential signal,
the third capacitor and the fourth capacitor are coupled between a second port of the isolation capacitor unit and the reference ground, with a common end configured to input/output the other polarity of the differential signal.

8. The digital isolator according to claim 7, wherein the first port of the isolation capacitor unit in the first isolation unit is coupled with the first port of the isolation capacitor unit in the second isolation unit through a first bonding wire,
the second port of the isolation capacitor unit in the first isolation unit is coupled with the second port of the isolation capacitor unit in the second isolation unit through a second bonding wire.

9. The digital isolator according to claim 7, wherein the capacitance values of the first capacitor and the third capacitor are equal to each other, and the capacitance values of the second capacitor and the fourth capacitor are equal to each other.

10. The digital isolator according to claim 7, wherein the capacitance value of the second capacitor is much greater than that of the first capacitor, and the capacitance value of the fourth capacitor is much greater than that of the third capacitor.

11. The digital isolator according to claim 1, wherein the first isolation unit and the second isolation unit are provided in different dies.

12. The digital isolator according to claim 1, wherein
the signal transmitting circuit comprises a shaping unit and a modulation unit;
the signal receiving circuit comprises a demodulation unit and a driving unit.

13. The digital isolator according to claim 12, wherein the shaping unit comprises a Schmitt trigger.

14. The digital isolator according to claim 12, wherein the signal transmitting circuit further comprises a first high-frequency oscillator, which is configured to generate a first high-frequency carrier signal.

15. The digital isolator according to claim 12, wherein the signal receiving circuit further comprises a second high-frequency oscillator configured to generate a second high-frequency carrier signal.

16. A system comprising:
a first circuit, configured to provide an input signal;
the digital isolator according to claim 1, comprising:
an isolation circuit comprising:
a first isolation unit, configured to convert a received input modulation signal corresponding to the input signal into a differential signal;
a second isolation unit, configured to provide an output modulation signal in response to receiving the differential signal, wherein the first isolation unit and the second isolation module have symmetrical circuit structures; and
a second circuit, configured to receive an output signal corresponding to the output modulation signal, wherein the first circuit and the second circuit are configured to operate at different voltage levels.

17. The system according to claim 16, wherein the digital isolator further comprises:
a signal transmitting circuit, configured to shape and modulate a received input signal to generate an input modulation signal. And
a signal receiving circuit, configured to demodulate the output modulation signal to generate the output signal.
